(19) United States
(12) Patent Application Publication
(10) Pub. No.: US 2025/0182921 A1
(43) Pub. Date: Jun. 5, 2025

(54) Neutron shielding materials selection method

(71) Applicant: Tokamak Energy Ltd, Oxfordshire (GB)

(72) Inventors: Gurdeep Kamal, Oxfordshire (GB); Matthew I. Brand, Sydney (AU); Patrick A. Burr, Sydney (AU); Edward G. Obbard, Sydney (AU)

(21) Appl. No.: 18/875,960

(22) PCT Filed: Jun. 23, 2023
(86) PCT No.: PCT/EP2023/067190

§ 371 Date: Dec. 17, 2024

(30) Foreign Application Priority Data
Jun. 24, 2022 (GB) 2209312.4

(51) Int. Cl. G21F 1/08; G06F 30/20

(52) U.S. Cl. CPC G21F 1/08; G06F 30/20

(57) ABSTRACT

A method of selecting one or more materials of specific isotopic composition for use in a neutron shield. A first list of materials is provided, each material having a different isotopic composition. Values of incident neutron fluxes ϕ_{g}⁰ that the neutron shield will encounter in use are provided. A set of criteria is provided, the set of criteria including one or more of: neutron flux, neutron dose, heating of a target protected by the neutron shielding, damage to the target, gas production within the target, tritium production within the target, and transmutation of the target. For each criterion, an overall weight β_{criteria} is defined, and an intrinsic weighting factor α_{g} is defined for each of a plurality of neutron energy groups based on the incident neutron fluxes. Using a computing system, an overall figure of merit Λ is calculated for each material in the first set of materials, wherein the overall figure of merit Λ for each material is based on: determining a figure of merit Λ_{g} for each neutron energy group based on absorption and scattering coefficients of the material for each neutron energy group; for each criterion, determining a figure of merit Λ_{criteria} for the criterion based on the figures of merit for each neutron energy group, weighted by the intrinsic weighting factors for the criterion; determining an overall figure of merit Λ based on the figures of merit for each criterion, weighted by the overall weight for the criterion. A second list of materials is selected based on the overall figures of merit Λ of the materials, wherein the second list is a subset of the first list.

### FIELD OF THE INVENTION

The present invention relates to neutron shielding, particularly, though not exclusively, for use in tokamak fusion reactors.

### BACKGROUND

The challenge of producing fusion power is hugely complex. Fusion neutrons are produced when a deuterium-tritium (D-T) or deuterium-deuterium (D-D) plasma are heated so that the nuclei have sufficient energy to overcome the Coulomb electrostatic repulsion to fuse together, releasing energetic neutrons and fusion products (e.g. ⁴He for D-T). To date, the most promising way of achieving this is to use a tokamak device; in the conventional tokamak approach to fusion (as embodied by ITER), the plasma needs to have high confinement time, high temperature, and high density to optimise this process.

A tokamak features a combination of strong toroidal magnetic field BT, high plasma current I_{ρ}and usually a large plasma volume and significant auxiliary heating, to provide a hot stable plasma so that fusion can occur. The auxiliary heating (for example via tens of megawatts of neutral beam injection of high energy H, D or T) is necessary to increase the temperature to the sufficiently high values required for nuclear fusion to occur, and/or to maintain the plasma current.

In order to ensure that the reactor is as compact as possible (which allows greater efficiency, particularly for a “spherical tokamak” plasma configuration), the thickness of neutron shielding should be reduced as much as possible, while still maintaining adequate protection for the other components. Minimising the distance between the plasma and the field coils allows a higher magnetic field in the plasma with a lower current in the coils.

### SUMMARY

According to a first aspect, there is provided a method of selecting one or more materials of specific isotopic composition for use in a neutron shield. A first list of materials is provided, each material having a different isotopic composition. Values of incident neutron fluxes ϕ_{g}⁰ that the neutron shield will encounter in use are provided. A set of criteria is provided, the set of criteria including one or more of: neutron flux, neutron dose, heating of a target protected by the neutron shielding, damage to the target, gas production within the target, tritium production within the target, and transmutation of the target. For each criterion, an overall weight β_{criteria} is defined, and an intrinsic weighting factor α_{g} is defined for each of a plurality of neutron energy groups based on the incident neutron fluxes. Using a computing system, an overall figure of merit Λ is calculated for each material in the first set of materials, wherein the overall figure of merit Λ for each material is based on:
determining a figure of merit Λ_{g} for each neutron energy group based on absorption and scattering coefficients of the material for each neutron energy group;
for each criterion, determining a figure of merit Λ_{criteria} for the criterion based on the figures of merit for each neutron energy group, weighted by the intrinsic weighting factors for the criterion;
determining an overall figure of merit A based on the figures of merit for each criterion, weighted by the overall weight for the criterion.
   A second list of materials is selected based on the overall figures of merit Λ of the materials, wherein the second list is a subset of the first list.

According to a second aspect, there is provided a method of selecting one or more materials of specific isotopic composition for use in a neutron shield. A first list of materials is provided, each material having a different isotopic composition. A distribution of incident neutron fluxes that the neutron shield will encounter in use is provided. A set of criteria is provided, the set of criteria including one or more of: neutron flux, neutron dose, heating of a target protected by the neutron shielding, damage to the target, gas production within the target, tritium production within the target, and transmutation of the target. For each criterion, an overall weight is defined, and an intrinsic weighting function is defined dependent on neutron energy based on the incident neutron fluxes. Using a computing system, an overall figure of merit for each material in the first set of materials is calculated, wherein the overall figure of merit for each material is based on:
determining a figure of merit function dependent on neutron energy based on neutron energy dependent absorption and scattering coefficients of the material;
for each criterion, determining a figure of merit for the criterion based an integration of the product of the intrinsic weighting function and the figure of merit function;
determining an overall figure of merit based on the figures of merit for each criterion, weighted by the overall weight for the criterion.
   A second list of materials is selected based on the overall figures of merit of the materials, wherein the second list is a subset of the first list.

According to a third aspect, there is provided the use of scandium borohydride, ScB₃H₁₈, or nickel hydride, NiH₂ as a neutron shielding material.

According to a fourth aspect, there is provided a neutron shield comprising scandium borohydride, ScB₃H₁₈, or nickel hydride, NiH₂.

Further embodiments are presented in claim 2 et seq.

### BRIEF DESCRIPTION OF THE DRAWINGS

FIGS. 1A, 1B and 1C are charts showing candidate neutron shielding materials according to respective exemplary figures of merit;

FIGS. 2A and 2B are charts showing candidate neutron shielding materials according to further exemplary figures of merit;

FIG. 3 is a chart showing candidate neutron shielding materials according to a yet further exemplary figure of merit, for three different weightings; and

FIG. 4 is a flowchart of a method of selecting neutron shielding materials.

### DETAILED DESCRIPTION

In order to provide more efficient neutron shielding (i.e. greater neutron attenuation for a particular thickness of shielding), materials must be found which block neutrons effectively. Neutrons can be blocked from penetrating further into a material via either scattering or by being absorbed. The neutron flux as a function of distance attenuates due to both mechanisms. However, finding such materials by experimentation alone is impractical given the number of potential compounds of interest, and finding such materials by detailed simulation is computationally expensive.

As such, the below disclosure provides a relatively simple to calculate “figure of merit” for neutron shielding materials, which quantifies the usefulness of a material as neutron shielding for a particular application. This figure of merit can then be used to determine suitable materials for use as neutron shielding, or for further study e.g. to determine suitability with respect to other engineering constraints.

The figure of merit proposed herein is based on a diffusion model of neutron transport. While the use of the figure itself does not rely on the complete derivation, details of the derivation of the figure are provided here for context. Symbols used are defined at the end of the description.

The Neutron Transport Equation is expressed as follows:

$$[ \frac{1}{v} \frac{\partial }{\partial t} + Ω \cdot ∇ + \sum ( r , E , t ) ] ϕ ( r , Ω , E , t ) = {\int }_{0}^{∞} {dE}^{′} {\int }_{4 π} d {Ω}^{′} {\sum }_{s} ( r , {Ω}^{′} \cdot Ω , {E}^{′} \to E , t ) ϕ ( r , {Ω}^{′} , {E}^{′} , t ) + \frac{χ ( E )}{4 π} {\int }_{0}^{∞} {dE}^{′} {\int }_{4 π} d {Ω}^{′} v ( {E}^{′} ) {\sum }_{f} ( r , {E}^{′} , t ) ϕ ( r , {Ω}^{′} , {E}^{′} , t ) + S ( r , Ω , E , t ) \qquad 1 )$$

However, in a low absorbing, strongly scattering medium, in the absence of fission, diffusion can be described by a simplified conservation statement (equation 2)

$$\frac{1}{v} \frac{\partial ϕ}{\partial t} = S - {\sum }_{a} ϕ - ∇ \cdot J \qquad 2 )$$

On the assumption that neutron scattering in a bulk material is linearly isotropic (i.e. has weak dependence on position within the material or the angle of travel of the neutrons), this can be presented in an alternative form via Fick's Law

$$J = - D ∇ ϕ , D = \frac{1}{3 [ {\sum }_{a} + {\sum }_{s} ( 1 - \overline{μ} ) ]} \qquad 3 )$$

$$\frac{1}{v} \frac{\partial ϕ}{\partial t} = S - {\sum }_{a} ϕ + D {∇}^{2} ϕ$$

“Definition of the diffusion coefficient in scattering and absorbing media”, Elaloufi et al, j. Opt. Soc. Am. A/Vol. 20, No. 4/April 2003 described a definition of the diffusion coefficient for photons in scattering and absorbing media. The same derivation applies to neutrons. Within a slab of neutron absorbing material, one term will dominate and the angular flux can be expressed as below.

$$\begin{matrix}ψ ( x , μ ) = A {g}_{0} ( μ ) exp ( - {k}_{0} x ) \\ ϕ ( x ) = {\int }_{- 1}^{1} ψ ( x , μ ) d μ\end{matrix}$$

This gives a coefficient D of:

$$D = \frac{〈 {g}_{0} 〉}{{\sum }_{a} + {\sum }_{S} ( 1 - \overline{μ} )} , 〈 {g}_{0} 〉 = {\int }_{- 1}^{1} {μ}^{2} {g}_{0} ( μ ) d μ \qquad 4 )$$

<g₀> is a measure of the anisotropy of the scattering. For purely isotropic scattering, <gₒ>=⅓, and for purely forward scattering <g₀>=1 (with μ̅=1). Pure absorption is mathematically the same as purely forward scattering, i.e. <g₀>=1 and μ̅=1, and additionally Σₛ=0 (as there is no scattering).

The appropriate value of <g₀> for the model will depend on the neutron energy and the material, and can be found by numerically solving the Neutron Transport Equation (equation 1), using empirical equations fitted to the solutions of the Neutron Transport Equation, or by fitting simulation or experimental data for a neutron energy group within a given material to the equation

$$ϕ ( x ) = {ϕ}_{0} exp ( - \sqrt{\frac{{\sum }_{a}}{D}} x )$$

i.e. by finding the value of <g₀> which best fits the input data by methods as known in the art (e.g. least squared error).

Stepping back to a simpler model, attenuation of neutrons within a material, in a region that does not contain a material boundary or a neutron source, is governed by a function ƒ.

$$\frac{ϕ}{{ϕ}_{0}} = f ( Λ t )$$

The function ƒ will differ depending on the geometry of the material, but it will always be a monotonically decreasing function—i.e. neutrons will in all materials where neutron multiplication cross-sections are less than the absorption cross-section be absorbed as they travel through the material, so the number of neutrons must decrease over distance (thickness), t. Λ is the macroscopic attenuation coefficient, and greater Λ represents improved behaviour of the material as a neutron attenuator—i.e. Λ is the desired figure of merit. The function ƒ does not need to be further specified to determine the figure of merit—for all monotonically decreasing functions, increased Λ will result in increased neutron attenuation. As some examples, for a simple 1D slab of material, the function ƒ is a decreasing exponential, and for annular geometries the function ƒ is one of the family of Modified Bessel Functions (or Modified Spherical Bessel Functions for spherical geometries). The choice of the function ƒ may scale Λ by some multiple (e.g. for a first geometry, the function ƒ may be some function of a Λt, and for a second geometry the function ƒ may be some function of bΛt, where a and b are both constant), but this would not change the ordering of materials using Λ or a figure of merit derived from Λ.

From the above discussion on diffusion, it can be found that, in a multigroup energy approximation, where the subscript _{g} indicates applicability to a given energy group:

$$\begin{matrix}{Λ}_{g} = \sqrt{\frac{{\sum }_{R , g}}{{D}_{g}}} \\ {D}_{g} = \frac{{〈 {g}_{0} 〉}_{g}}{{\sum }_{R , g} + {\sum }_{s , g}^{′}} \\ {\sum }_{R , g} = {\sum }_{a , g} + {\sum }_{s , g \to {g}^{′}} \\ {\sum }_{s , g}^{′} = {\sum }_{s , g \to g} ( 1 - {\overline{μ}}_{g} ) \\ \sum = N σ\end{matrix}$$

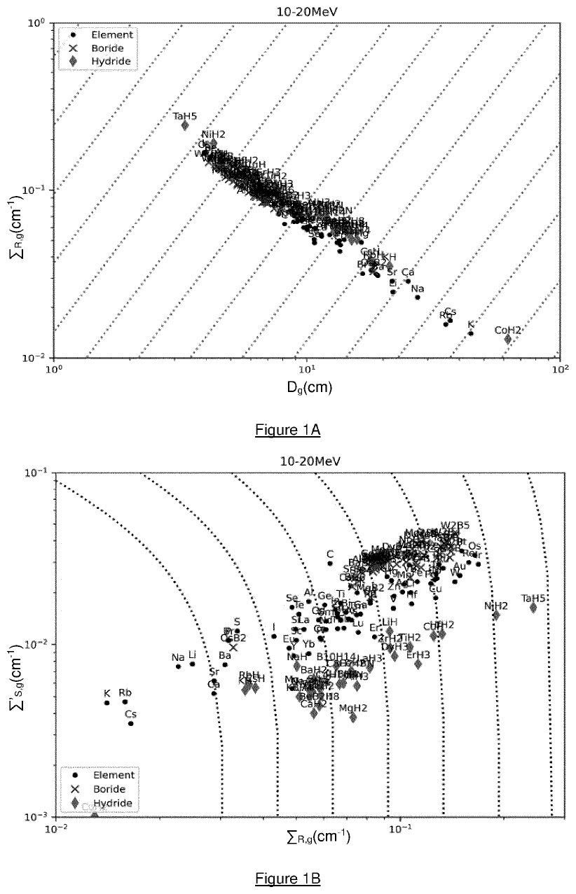

FIGS. 1A, 1B, and 1C illustrate three potential graphical representations of the figure of merit Λ_{g}, their associated tie lines, and a selection of candidate materials.

FIG. 1A illustrates the figure of merit for a given energy group

$${M}_{1} = {Λ}_{g} = \sqrt{\frac{{\sum }_{R , g}}{{D}_{g}}} ,$$

shown by plotting Σ_{R,g} against D_{g} on a log-log scale. The top left corner of the graph in FIG. 1A indicates greater M₁, and tie lines (lines of equal M₁) are shown as dotted lines on the figure and form equally spaced diagonal straight lines on the log-log plot. While M₁ is a suitable figure of merit, in that better performing materials will have greater M₁, it does not provide good separation between materials, as can be seen by the clustering of results. In part, this is because D_{g} is a function of Σ_{R,g}, so the materials cluster around a line in the graph.

An alternative figure of merit for a given energy group, M₂, can be obtained by the use of the below relationship:

$${Λ}_{g} = \sqrt{\frac{{\sum }_{R , g}}{{D}_{g}}} = \sqrt{\frac{{\sum }_{R , g} ( {\sum }_{R , g} + {\sum }_{s , g}^{′} )}{{〈 {g}_{0} 〉}_{g}}}$$

Using the additional assumption that <g₀>_{g} is constant for all materials within a given energy group, this leads to the figure of merit M₂={square root over (Σ_{R,g}(Σ_{R,g}+Σ′_{s,g})}) , as shown in FIG. 1B, which is a plot of Σ_{R,g} against Σ′_{s,g}. In this figure, M₂ increases towards the right of the figure, and tie lines have the equation below:

$${\sum }_{s , g}^{′} = \frac{{Λ}_{g}^{2} {〈 {g}_{0} 〉}_{g} - {\sum }_{R , g}^{2}}{{\sum }_{R , g}}$$

This improves the separation of materials, allowing candidates to be more easily distinguished, but the representation is less intuitive due to the curved tie lines, and the assumption that <g₀>_{g} is constant will not hold for all materials.

A further alternative representation can be obtained by further decomposing Λ_{g}.

$${Λ}_{g} = \sqrt{\frac{{\sum }_{R , g}}{{D}_{g}}} = \sqrt{\frac{{\sum }_{R , g} ( {\sum }_{R , g} + {\sum }_{s , g}^{′} )}{{〈 {g}_{0} 〉}_{g}}} = \sqrt{{N}^{2} \frac{{σ}_{R , g} ( {σ}_{R , g} + {σ}_{s , g}^{′} )}{{〈 {g}_{0} 〉}_{g}}} = N {λ}_{g}$$

$${M}_{3} = N \sqrt{( \frac{{σ}_{R , g} ( {σ}_{R , g} + {σ}_{s , g}^{′} )}{{〈 {g}_{0} 〉}_{g}} )} = N {λ}_{g}$$

This is shown in FIG. 1C, which is a plot of N against Λ_{g}, with M₃ increasing towards the top right of the figure. This representation provides good separation of the materials, linear tie lines (when plotted on a log-log scale), and additionally N provides a useful proxy for the material's physical properties, and λ_{g} provides a useful indication of a material's nuclear properties.

In each of the above examples, the actual figure of merit for a given energy group, which should be maximised, is Λ_{g} (or, in the case of M₂, proportional to Λ_{g} on the assumption of constant <g₀>), the representations merely provide a useful illustration, or secondary figures of merit such as λ_{g}.

The values of each Σ (and σ) depend on neutron energy, and so the above analysis considers an average performance over a given neutron energy group based on the values of Σ used. Depending on the energy group chosen, the ranking of materials will change, due to their different scattering and absorption properties at different energy levels. In practice, it is generally more useful to analyse the performance as a weighted average over multiple energy groups, e.g. weighted by how much each group contributes to heating or damage of the materials to be protected.

Neutrons of different energies will have different effects on the material needing to be shielded. To combine the figures of merit Θ_{g} for each energy group, a weighting factor α_{g} based on the intrinsic cross-sectional properties of the material to be shielded is used to obtain a metric for a given criteria Λ_{criteria}

$${Λ}_{criteria} = {\sum }_{g} {α}_{g} {Λ}_{g}$$

While the above shows a “binning” approach where constants α_{g} are calculated for each of a plurality of energy groups, a continuous approach may be used where a function A is defined, where A depends on the neutron energy, and the overall penalty function can then be calculated as the integral of AΛ over all neutron energies (though A may be 0 outside of a range of interest, which is equivalent to only integrating over that range of interest). The constants α_{g} may be normalized such that Σ_{g}α_{g}=1, or equivalently the function A may be normalised such that ∫₀^{∞}AdE=1.

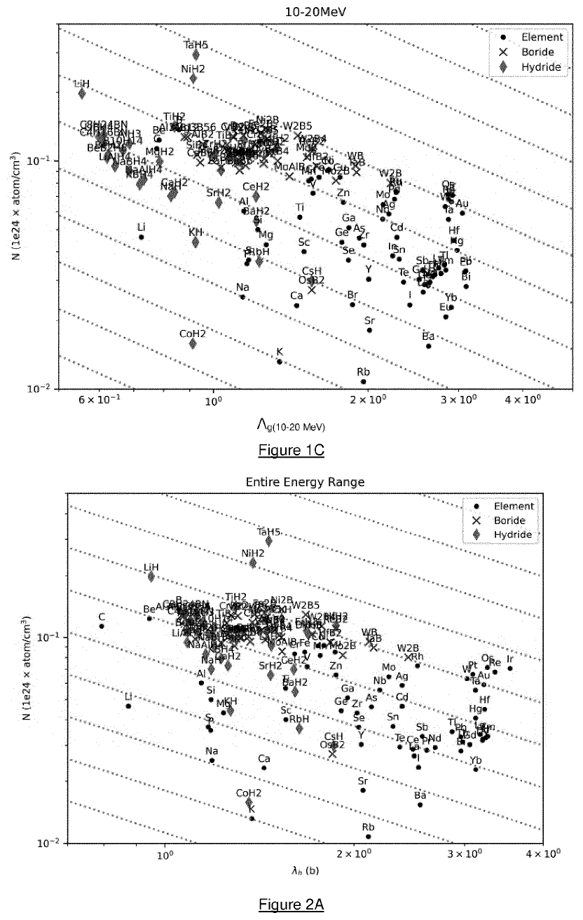

The choice of criteria and α_{g} depends on the required weighting for a given design parameter. For example, where the shielding is intended to protect against neutron heating, an appropriate choice of α_{g} (or the function A) would be the KERMA k_{g} (Kinetic Energy Released in Material—a measure of the kinetic energy that a given neutron energy would deposit in a given material) of the material being protected. In this way, neutron groups which generate more heat have a greater weight attributed to them, and contribute more to the figure of merit for the neutron heating criterion—i.e. attenuation of the “more problematic” neutrons is favoured. This is shown for a ReBCO superconductor material in FIG. 2A.

As a further example, when considering the potential for neutron damage to ReBCO HTS, a suitable set of constants is α_{g}∝(0.8T_{dam,g})/(2E_{d}), which is a measure of the ballistic energy available for atomic displacement within the ReBCO (ignoring properties which would be constant between energy groups, and hence can be neglected as they would factor out when normalized). FIG. 2B shows a graph of this measure.

Other examples include: using energy cutoffs to account for the flux in a given energy region agnostic to the material being protected; the absorption cross section to account for activation/transmutation of the material, gas production cross sections to account for the amount of gaseous particles produced in the material, and dose weighting factors to account for health effects.

KERMA, the ballistic energy available for atomic displacement, absorption cross sections, gas production cross sections, dose weighting factors, and similar values can be obtained from standard reference tables and simulation techniques as known in the art.

An additional set of scale factors may be applied to each energy group (or as an additional continuous function) to account for the expected flux profile of the incoming neutrons.

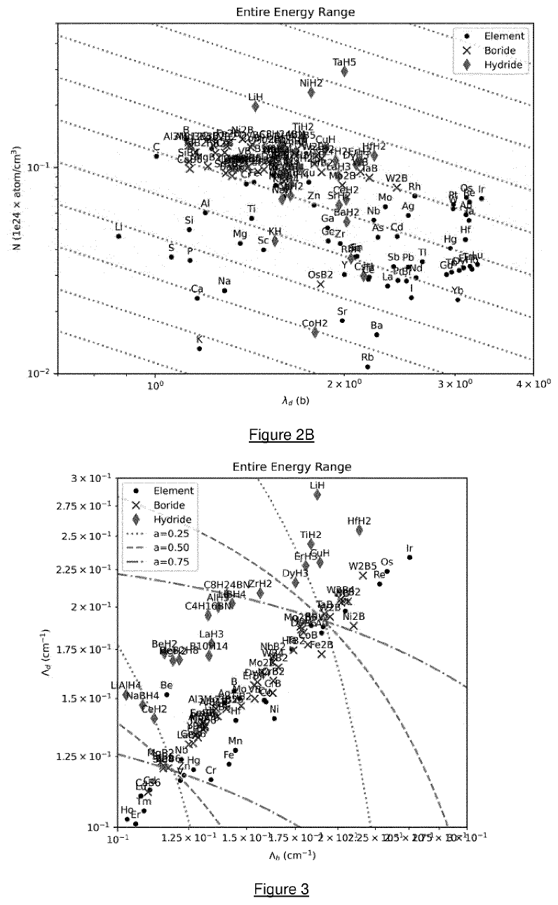

In practice, there is generally a need to balance multiple design considerations—e.g. a material which is an effective shield against neutron heating may not be suitable if there is a more effective shield against neutron damage which is still adequate against heating. However, this can be taken into account by determining A for various sets of constants α_{g} corresponding to the required design goals, and then taking a weighted average (or other linear function) of the Λ obtained. For the heating example above Λₕ, and the damage example above Λ_{d}, a plot of Λₕvs Λ_{d} is shown in FIG. 3, with each set of dashed lines representing tie lines for a different weighting of Λₕ vs Λ_{d}, where (1−β)Λₕ+βΛ_{d}=Λₜₒₜ.

When considering a material as a shield, multiple of these effects need to be considered, with the relative importance of each of these criteria depending on the radiation environment being considered. A set of weighting factors β is used to combine all these criteria into a single overall figure of merit Λ

$$Λ = {\sum }_{criteria} {β}_{criteria} \frac{{Λ}_{criteria}}{max ( {Λ}_{criteria} )}$$

Where the figure of merit for each criteria Λ_{criteria} is normalised by the maximum value max (Λ_{criteria}) of that metric for all shield materials being considered so that the different criteria can be more easily compared and combined

For an example of a fusion power reactor (FPP) and the shielding of a ReBCO HTS magnet, the shield needs to block slow (E<0.1MeV) and fast (E≥0.1MeV) neutrons, prevent atomic displacements (damage) in the HTS, and prevent transmutations within the HTS. A numerical example of relevant weighting factors for β in this scenario and how they relate to the intrinsic cross sections of the material being shielded is provided in the Table below

| | Criteria | | |
|---|---|---|---|
| | weighting | Intrinsic Weighting | |
| Criteria | β_{criteria} | Factor α_{g} | Intrinsic Cross section description |
| Total flux | 0 | ϕ_{g}⁰ | |
| Slow Flux | 0.6 | ϕ_{g}⁰H(0.1 MeV − E_{g}) | $H ( x ) = \{ \begin{matrix}0 , x \leq 0 \\ 1 , x > 0\end{matrix} , Heaviside step$ |
| Fast Flux | 1.0 | ϕ_{g}⁰H(E_{g} − 0.1 MeV) | function |
| Heat | 0 | ϕ_{g}⁰k_{g}^{Target} | k = KERMA |
| Damage | 0.3 | ϕ_{g}⁰T_{g}^{Target} | T = dpa cross section |
| Transmutation | 0.2 | ϕ_{g}⁰σ_{a,g}^{Target} | σₐ = absorption cross section |
| Neutron Dose | 0 | ϕ_{g}⁰W_{R,g} | W_{R} = a dose response function, e.g. |
| | | | ICRP103 response function |
| Gas | 0 | ϕ_{g}⁰σ_{g}(n, X)^{Target} | σ(n, X) = total particle production |
| Production | | | cross section for H, D, T, 3He and 4He |
| Tritium | 0 | ϕ_{g}⁰σ_{g}(n, xT)^{Target} | σ(n, xT) = T particle production cross |
| Production | | | section |

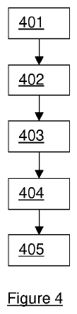

Whichever of the above related figures of merit is used, FIG. 4 is a flowchart of a method of selecting neutron shielding materials. In step 401, a plurality of initial candidate materials are chosen, i.e. a first set of materials. This may be a broad group such as “metal hydrides” or “metal borides”. In step 402, values of incident neutron fluxes are provided, representing the expected neutron flux that the shield will encounter in use. In step 403, a set of criteria is provided for evaluating the figure of merit, which may include any of the criteria in the table above. Where these criteria refer to a target (e.g. heat or damage to the target), the properties of that target will be selected representative of the expected use of the neutron shielding. In step 404, an overall weight is defined for each criterion, and a set of intrinsic weight factors for each neutron energy group based on the incident neutron fluxes, for each criterion. In step 405, a computer system is used to calculate an overall figure of merit for each material in the candidate list, based on:
Determining a figure of merit for each neutron energy group based on absorption and scattering coefficients of the material for that energy group,
Determining a figure of merit for each criterion based on the figures of merit for each energy group, weighted by the intrinsic weighting factors of the criterion,
Determining an overall figure of merit based on the figures of merit for each criterion, weighted by the overall weight for the criterion.
   A shortlist, i.e. second set, of materials is then selected based on the overall figures of merit of the materials.

In particular, the isotropy of the scattering is likely to be the least reliably estimated quantity used in the figure of merit. As such, the threshold proportion of the “best performing” figure of merit may be calculated such that, if <g₀>is estimated incorrectly, any material which should be the best performing material would still be above the threshold—e.g. since Λ depends on the inverse square root of <g₀> and <g₀> could take a value between 1 and ⅓, then the worst case is that the apparent best performing material was calculated with a <g₀> of ⅓, but in fact has a <g₀> of 1. The threshold to ensure that any material which should be best performing in the case of a worst-case incorrect estimation of <g₀> is within the selected set/3 is 1/\sqrt{3}≈57.7% of the best performing material. In practice, a greater threshold may be used, as a material with <g₀>=⅓ would have pure isotropic scattering, which is unlikely to be relevant to neutron shielding applications. Such an approach allows for an initial approximation of constant <g₀> for all materials to be used, which can then be refined for the candidate list with figure of merit above the threshold, e.g. by numerical evaluation, experiment or Monte-Carlo simulation to determine an accurate value of <g₀> for each material. Once an accurate value is determined, the figures of merit for each material may be re-calculated, and a further threshold applied to narrow down the candidate list. This approach significantly simplifies the selection of the candidate list, since the calculation of <g₀> can otherwise be complex, and this approach reduces the number of materials for which <g₀> must be determined.

Review of the figures of merit according to the above methods has presented two candidate materials not previously suggested for use in neutron shielding—nickel hydride (NiH₂), and scandium borohydride, ScB₃H₁₈. NiH₂ can be formed by reacting nickel with hydrogen at high pressure (˜60 GPa), and is stable at cryogenic temperatures, making it particularly suitable for environments such as a spherical tokamak where cryogenic systems are already present. ScB₃H₁₈ can be formed by ball milling of scandium chloride hydrate and lithium borohydride, and has particular further advantages in that even when it begins to break down, it remains as a scandium and boron compound (i.e. only the hydrogen is released) and retains at least some of its shielding performance, e.g. better shielding performance than metallic scandium.

The increased neutron attenuation for a given thickness of neutron shielding may be used to provide improved attenuation for shielding of a set thickness compared to known shielding materials, or it may be used to provide a similar degree of neutron shielding with a reduced thickness compared to known shielding materials. The latter is particularly useful in applications such as the central column of a spherical tokamak fusion reactor, where the minimising the thickness of the shielding (as part of minimising the overall diameter of the central column) is an important design goal.

### Listing of Terms in Equations

Unless otherwise stated for a particular equation, each symbol used in this document has a consistent meaning as per the list below, wherever it appears.

Note that in equation 1), and in the description of the Elaloufi paper, brackets represent the variables on which a quantity depends, whereas elsewhere in the document brackets are used for arithmetic grouping. Mathematical operators take their normal meaning.

In general, unless specified, a subscript 0 indicates normalisation or scale value for a particular quantity, i.e. such that A=A₀f(x) for some quantity A, with A₀ being a constant.

| Symbol | Meaning |
|---|---|
| ν | Neutron velocity vector |
| t | Time |
| E | Energy |
| r | Position vector |
| Ω | Unit vector (solid angle) in direction of motion |
| Σ (no subscript) | Total neutron interaction cross section |
| ϕ | Scalar neutron flux |
| Σₛ | Scattering cross section |
| χ | Probability density function for neutrons produced by fission |
| Σ_{f} | Fission cross section |
| S | Source term |
| Σₐ | Neutron absorption cross section |
| J | Diffusion flux |
| D | Diffusion coefficient |
| μ | Scattering cosine (with a bar above indicating the mean, where used) |
| Ψ | Angular neutron flux |
| <g₀> | An indication of anisotropy of scattering, for purely isotropic scattering, |
| | <g₀> = 1/3, and for purely forward scattering <g₀> = 1 (with μ̅ = 1). |
| Λ | Macroscopic attenuation coefficient - also the desired figure of merit |
| Σ_{R} | Removal cross section (i.e. the likelihood of a neutron in a given energy |
| | group being removed from the population at that energy group by |
| | absorption or scattering) |
| Σ_{s, g->g′} | Out of group scatter cross section (i.e. cross section for scattering |
| | between energy groups) |
| Σ_{s, g->g} | In group scattering cross section (i.e. cross section for scattering within |
| | an energy group) |
| Σ′ₛ | Modified in group scattering cross section, taking into account directional |
| | change. |
| N | Atomic number density |
| σ | Microscopic cross section (i.e. probability of a given reaction occurring |
| | for a single atomic nucleus. Any subscripts use specify the equivalent |
| | cross section to the corresponding macroscopic cross section Σ) |
| α_{g} | Energy group coefficients |
| Z = Λ_{eff} | Effective attenuation coefficient |
| k_{g} | KERMA coefficients - a measure of the kinetic energy that a given |
| | neutron energy would deposit in a given material |
| T_{dam} | Ballistic damage energy available to create displacements in the material |
| E_{d} | Threshold displacement energy - the energy required to displace an |
| | atom from its position in a crystal lattice |
| Subscript g | The property described above for a given energy group g |

1. A method of selecting one or more materials of specific isotopic composition for use in a neutron shield, the method comprising:
providing a first list of materials, each material having a different isotopic composition;
providing values of incident neutron fluxes ϕ_{g}⁰ that the neutron shield will encounter in use;
providing a set of criteria, the set of criteria including one or more of:
neutron flux,
neutron dose,
heating of a target protected by the neutron shielding,
damage to the target,
gas production within the target,
tritium production within the target, and
transmutation of the target;
for each criterion, defining an overall weight β_{criteria}, and an intrinsic weighting factor α_{g} for each of a plurality of neutron energy groups based on the incident neutron fluxes;
calculating, using a computing system, an overall figure of merit Λ for each material in the first set of materials, wherein the overall figure of merit Λ for each material is based on:
determining a figure of merit Λ_{g} for each neutron energy group based on absorption and scattering coefficients of the material for each neutron energy group;
for each criterion, determining a figure of merit Λ_{criteria} for the criterion based on the figures of merit for each neutron energy group, weighted by the intrinsic weighting factors for the criterion;
determining an overall figure of merit Λ based on the figures of merit for each criterion, weighted by the overall weight for the criterion;
selecting a second list of materials based on the overall figures of merit Λ of the materials, wherein the second list is a subset of the first list.

2. A method according to claim 1, and comprising selecting a single selected material from the second list of materials;

3. A method according to claim 2, and comprising using the selected material as a neutron shield.

4. A method according to claim 2, and comprising, for each material of the second list, performing one or more further selection steps, wherein the further selection steps comprise one or more of:
using a derived fit towards empirical equations to the solution of the neutron transport equation for each material of the candidate list for the selection of <g₀>_{g};
performing neutron attenuation experiments for each material of the candidate list for the selection of <g₀>_{g};
performing neutron transport simulations for each material of the candidate list for the selection of <g₀>_{g},
wherein the selected material is selected based on said further selection steps; and
where <g₀>_{g} is a term indicating the absorption and the isotropy of scattering in each energy group g such that for purely isotropic scattering, <g₀>_{g}=⅓, for purely forward scattering <g₀>_{g}=1, for purely absorbing <g₀>_{g}=1, and for intermediate conditions ⅓<<g₀>_{g}<1.

5. A method according to claim 1, wherein selecting the second list comprises selecting all materials of the first list for which the figure of merit is above a threshold.

6. A method according to claim 5, wherein the threshold is a proportion of the highest figure of merit of the materials of the initial list of materials.

7. A method according to claim 6, wherein said proportion is at least 57%

8. A method according to claim 1, wherein the figure of merit Λ_{g}, for each energy group, is proportional to
$$\sqrt{\frac{{\sum }_{R , g}}{{D}_{g}}} ,$$
where the diffusion coefficient D_{g} is proportional to
$$\frac{1}{{\sum }_{R , g} + {\sum }_{s , g}^{′}} ,$$
with Σ′_{s,g}=Σ_{s,g→g}(1−μ̅_{g}) and Σ_{R,g}=Σ_{a,g}+Σ_{s,g→g}′, where for each material of the list of materials and for each energy group g, Σ_{R,g} is the neutron removal cross section, Σ_{s,g->}is the in-group neutron scattering cross section, Σ_{s,g->g′}is the out-of-group neutron scattering cross section, Σ′s is a modified neutron scattering cross section, Σ_{a,g} is the neutron absorption cross section, and μ̅_{g} , is the mean scattering cosine.

9. A method according to claim 8, wherein
$${D}_{g} = \frac{{〈 {g}_{0} 〉}_{g}}{{\sum }_{s , g} + {\sum }_{s , g}^{′}} , where {\sum }_{s , g}^{′} = {\sum }_{s , g \to g} ( 1 - {\overline{μ}}_{g} )$$
and Σ_{R,g}=Σ_{a,g}+Σ_{s,g→g′}, where <g₀>_{g} is a term indicating the absorption and the isotropy of scattering in each energy group g such that for purely isotropic scattering, <g₀>_{g}=⅓, for purely forward scattering <g₀>_{g}=1, for purely absorbing <g₀>_{g}=1, and for intermediate conditions ⅓<<g₀>_{g}<1.

10. A method according to claim 8, where the figure of merit for each energy group Λ_{g} is proportional to {square root over (Σ_{R,g}(Σ_{R,g}+Σ′_{s,g})}.

11. A method according to claim 1, wherein figure of merit for each energy group Λ_{g} is based on the neutron absorption and scattering cross sections for each energy group of each material and the atomic number density N of each material.

12. A method according to claim 11, wherein
the figure of merit for each energy group Λ_{g} is proportional to Nλ_{g}, where λ_{g} is a secondary figure of merit for each energy group and Aλ_{g} is proportional to
$$\sqrt{( \frac{{σ}_{R , g} ( {σ}_{R , g} + {σ}_{s , g}^{′} )}{{〈 {g}_{0} 〉}_{g}} )} ,$$
and
selecting a material based on the figure of merit comprises selecting a material based on both the figure of merit Λ_{g} and the secondary figure of merit λ_{g}, where σ_{R,g} is the microscopic neutron removal cross section, σ′_{s,g} is a modified microscopic neutron scattering cross section and
where <g₀>_{g} is a term indicating the absorption and the isotropy of scattering in each energy group g such that for purely isotropic scattering, <g₀>_{g}=⅓, for purely forward scattering <g₀>_{g}=1, for purely absorbing <g₀>_{g}=1, and for intermediate conditions ⅓<<g₀>_{g}<1.

13. A method according to claim 1, wherein the intrinsic weighting factors comprise:
where the criterion is neutron flux, the incident neutron flux within a specified energy range;
where the criterion is neutron dose, the incident neutron fluxes multiplied by a dose response function,
where the criterion is heat, the incident neutron fluxes multiplied by the kinetic energy released in material, KERMA, for the target, for neutrons in the energy group;
where the criterion is damage, the incident neutron fluxes multiplied by the ballistic energy available for atomic displacement, (0.8T_{dam,g})/(2E_{d}), for the target, for neutrons in the energy group, where T_{dam,g} is the available ballistic energy and E_{d} is the threshold displacement energy of the material;
where the criterion is gas production, the incident neutron fluxes multiplied by a coefficient for the rate of production of hydrogen and helium isotopes by the material for neutrons in the energy group,
where the criterion is transmutation, the incident neutron fluxes multiplied by an absorption coefficient of the material for neutrons in the energy group.

14. A method according to claim 1, wherein for each material, the neutron absorption and scattering cross sections are calculated based on the neutron absorption and scattering cross sections of each constituent isotope of the material.

15. A method of selecting one or more materials of specific isotopic composition for use in a neutron shield, the method comprising:
providing a first list of materials, each material having a different isotopic composition;
providing a distribution of incident neutron fluxes that the neutron shield will encounter in use;
providing a set of criteria, the set of criteria including one or more of:
neutron flux,
neutron dose,
heating of a target protected by the neutron shielding,
damage to the target,
gas production within the target,
tritium production within the target, and
transmutation of the target,
for each criterion, defining an overall weight, and an intrinsic weighting function dependent on neutron energy based on the incident neutron fluxes;
calculating, using a computing system, an overall figure of merit for each material in the first set of materials, wherein the overall figure of merit for each material is based on:
determining a figure of merit function dependent on neutron energy based on neutron energy dependent absorption and scattering coefficients of the material;
for each criterion, determining a figure of merit for the criterion based an integration of the product of the intrinsic weighting function and the figure of merit function;
determining an overall figure of merit based on the figures of merit for each criterion, weighted by the overall weight for the criterion;
selecting a second list of materials based on the overall figures of merit of the materials, wherein the second list is a subset of the first list.

16. Use of scandium borohydride, ScB₃H₁₈, or nickel hydride, NiH₂ as a neutron shielding material.

17. A neutron shield comprising scandium borohydride, ScB₃H₁₈, or nickel hydride, NiH₂.
